(19) United States
(12) Patent Application Publication
(10) Pub. No.: US 2017/0254841 A1
(43) Pub. Date: Sep. 7, 2017

(54) PHASE ANGLE DETERMINATION OF AC SIGNALS

(71) Applicant: QUALCOMM Incorporated, San Diego, CA (US)

(72) Inventors: Saeed Nejatali, San Diego, CA (US); Linda Irish, San Diego, CA (US); David Fern, Santee, CA (US); Francesco Carobolante, II, San Diego, CA (US)

(21) Appl. No.: 15/059,151

(22) Filed: Mar. 2, 2016

(51) Int. Cl. G01R 25/08

(52) U.S. Cl. CPC G01R 25/08

(57) ABSTRACT

Methods and circuitry are disclosed to produce a first signal representative of the AC voltage signal and a second signal representative of an AC current signal. The first and second signals may be combined with a clock signal to produce a third signal. A phase angle between the AC voltage signal and the AC current signal may be determined based on a pulse count indicative of how many pulses occur in the third signal over a predetermined period of time.

### TECHNICAL FIELD

The present disclosure relates generally to alternating current (AC) circuits, and in particular to phase angle measurements between AC signals.

### BACKGROUND

The measurement of alternating current (AC) power and impedance in an AC system is often made for various reasons. AC power and/or impedance may be measured or otherwise determined in order to improve power transfer efficiency (e.g., inductance switching) in the AC system.

Merely as an illustrative example, consider a wireless power transfer system. A power transmitting unit may include a transmit coil that can be driven by an AC current to generate a magnetic field. A power receiving unit (e.g., a smartphone, a wearable device, etc.) may include a receive coil that can magnetically couple to the magnetic field to receive power wirelessly when placed on the charging surface of the power transmitting unit. AC power and/or impedance measurements may be used to provide protective measures such as cross connection prevention, overload protection of the power amplifier, detection of foreign objects, and so on.

AC power and/or impedance measurements may be used to detect operating conditions in the AC system. In the wireless power transfer example, for instance, AC power and/or impedance measurements may be used to detect the presence of a power receiving unit on the charging surface, provide reverse in-band signaling, detect state machine transitions, and so on.

The measurement of alternating current (AC) power and impedance in an AC system typically requires determining the phase difference (phase angle) between AC voltage and AC current.

### SUMMARY

In accordance with the present disclosure, a method may include generating a first signal representative of an alternating current (AC) voltage signal and generating a second signal representative of an AC current signal. The first and second signals may be combined with a clock signal to produce a third signal. Phase angle information representative of a phase angle between the AC voltage signal and the AC current signal may be produced based on a pulse count indicative of how many pulses occur in the third signal over a predetermined period of time.

In some aspects, generating the first signal and the second signal may include producing respectively a first square wave from the AC voltage signal and a second square wave from the AC current signal.

In some aspects, combining the first and second signals with a clock signal may include logically AND'ing together the first signal, the second signal, and the clock signal.

In some aspects, combining the first and second signals with a clock signal may include combining the first and second signals to produce a combined signal and combining the combined signal with the clock signal. In some aspects, combining the first and second signals may include logically AND'ing together the first and second signals.

In some aspects, the method may further comprise providing the phase angle information to a controller in a wireless power transmitting device. The AC voltage signal and the AC current signal may be produced in the wireless power transmitting device.

In some aspects, the method may further comprise determining a sign of the phase angle based only on the first signal and the second signal.

In some aspects, producing phase angle information may include accessing data in a data table using the pulse count and determining the phase angle using the accessed data.

In some aspects, producing phase angle information may include evaluating a relationship between phase angle and the number pulses that occur in the third signal over the predetermined period of time.

In some aspects, the accuracy of the phase angle is independent of a frequency of the clock signal.

In accordance with the present disclosure, a method may include generating a first square wave signal representative of an AC voltage signal and generating a second square wave signal representative of an AC current signal. The method may further include generating a third square wave signal by combining at least the first square wave signal and the second square wave signal. A phase angle between the AC voltage signal and the AC current signal may be determined based on how many pulses occur in the third square wave in a predetermined period of time.

In some aspects, the method may further include determining a sign of the phase angle based only the first square wave signal and the second square wave signal.

In some aspects, determining the phase angle may be based on data obtained from accessing a data table using the number of events that occur in the predetermined period of time.

In some aspects, determining the phase angle may include evaluating a relationship between phase angle and the number of events that occur in the predetermined period of time.

In some aspects, the method may further include logically AND'ing together the first square wave signal, the second square wave signal, and a clock signal to produce a third square wave signal. The phase angle may be based on the number of pulses in the third square wave signal during the predetermined period of time.

In some aspects, the method may further include logically AND'ing together the first square wave signal and the second square wave signal to produce an intermediate square wave signal and combining the intermediate square wave signal with a clock signal to produce the third square wave signal.

In accordance with the present disclosure, a circuit may include a first circuit configured to generate a first signal representative of an AC voltage signal. A second circuit may be configured to generate a second signal representative of an AC current signal. A third circuit may be electrically connected to the first and second circuits and configured to combine the first and second signals with a clock signal to produce a third signal. The circuit may include a counter electrically connected to the third circuit and configured to produce a pulse count representative of a number of pulses occurring in the third signal over a predetermined period of time. A computing circuit may be electrically connected to the counter and configured to produce phase angle data representative of a phase angle between the AC voltage signal and the AC current signal using the pulse count.

In some aspects, the first circuit may be a comparator configured to receive the AC voltage signal and produce a first square wave signal therefrom. The second circuit may be a comparator configured to receive the AC current signal and produce a second square wave signal therefrom. In some aspects, either the first comparator or the second comparator may be further configured to produce an inverted square wave.

In some aspects, the third circuit may be an AND gate, the first and second signals may be electrically connected to respective first and second inputs of the AND gate. The clock signal may be provided to a third input of the AND gate. The third signal may be an output of the AND gate.

In some aspects, the third circuit may comprise an AND gate configured to logically AND together the first and second signals to produce an AND'd output and a D-type flip flop electrically connected to the AND gate to receive the AND'd output. The D-type flip flop may have a clock input configured to receive the clock signal. The D-type flip flop may be configured to produce the third signal.

In some aspects, the circuit may further include a fourth circuit electrically connected to the first and second circuits and configured to produce a signal indicative of whether the AC voltage signal leads or lags the AC current signal.

In some aspects, the circuit may further include a memory. The computing circuit may comprise a digital processor configured to access data from the memory using the pulse count and to produce the phase angle data using the data accessed from the memory.

In some aspects, the computing circuit may comprise a digital processor configured to generate the phase angle data using a relationship between the phase angle and the number of pulses that occur in the third signal over the predetermined period of time.

In accordance with the present disclosure, a circuit may include means for generating a first square wave signal representative of an AC voltage signal, means for generating a second square wave signal representative of an AC current signal, means for generating a third square wave signal from the first square wave, the second square wave, and a clock signal, and means for producing phase angle data based on a number of pulses that occur in the third square wave signal in a predetermined period of time.

In some aspects, the circuit may further include means for counting the number of pulses in the third square wave signal that occur during the predetermined period of time. The means for counting may be configured to provide the number of pulses counted to the means for producing.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. In the accompanying drawings:

FIG. 1 shows an AC circuit configured in accordance with the present disclosure.

FIGS. 1A and 1B illustrate an embodiment in accordance with the present disclosure.

FIG. 2 shows an embodiment of a phase detector in accordance with some embodiments of the present disclosure.

FIGS. 3 and 3A show timing diagrams in accordance with embodiments of the present disclosure.

FIG. 4 shows an embodiment of a phase detector in accordance with some embodiments of the present disclosure.

FIGS. 5 and 5A illustrate a relationship between pulse count and phase angle.

FIGS. 6A and 6B illustrate a relationship between pulse count and phase angle.

FIG. 7 illustrates processing in accordance with the present disclosure.

FIG. 8 shows an embodiment of a phase detector in accordance with some embodiments of the present disclosure.

FIGS. 9 and 9A show timing diagrams in accordance with embodiments of the present disclosure.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

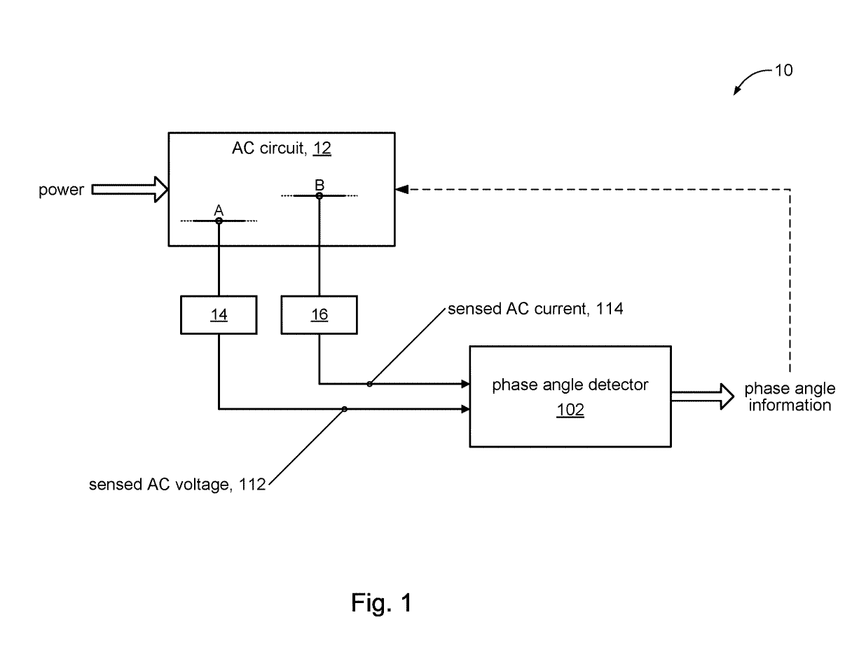

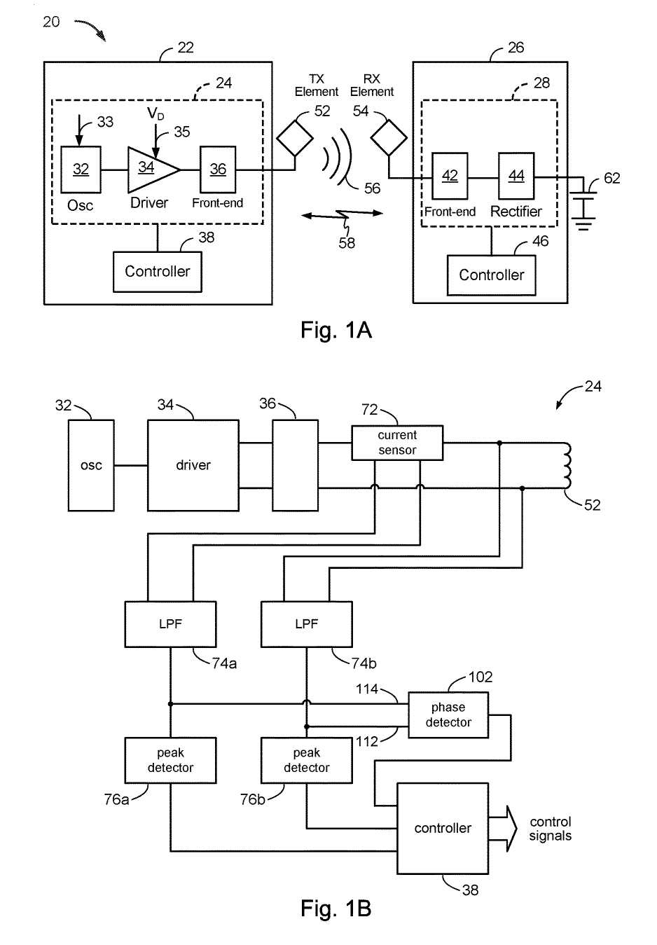

FIG. 1 shows a system 10 comprising an alternating current (AC) circuit 12 for which an AC power and/or an impedance measurement may be made. An AC voltage signal 112 may be sensed at a location A in the AC circuit 12. Likewise, an AC current signal 114 may be sensed at a location B in the AC circuit 12. Depending on the AC circuit 12, the locations A and B may be the location in the AC circuit 12, or the locations A and B may be different locations in the AC circuit 12.

In some embodiments, one or more interface circuits 14, 16 may be used to filter or otherwise condition the respective sensed AC voltage and AC current signals 112, 114. For example, the signal sensed at location A (and/or location B) may contain harmonic content, which can negatively affect the detection of phase angle. Accordingly, in some embodiments, the interface circuits 14, 16 may include filters to filter out the undesired harmonics to produce suitable AC voltage and AC current signals 112, 114, respectively. In some embodiments, the interface circuits 14, 16 may include amplification circuits to boost the sensed signals to adequate levels. In other embodiments, the interface circuits 14, 16 may include any suitable circuitry to otherwise “clean up” the signals sensed at respective locations A and B, to produce respective AC voltage and AC current signals that can be processed in accordance with the present disclosure.

A phase angle detector 102 in accordance with the present disclosure may receive the AC voltage signal 112 and the AC current signal 114. The phase angle detector 102 may produce or otherwise generate phase angle information representative of the phase difference (commonly expressed as phase angle) between the AC voltage signal 112 and the AC current signal 114. In some embodiments, the phase angle information may be digital (e.g., a signed number). In other embodiments, the phase angle information may be analog (e.g., a plus or minus voltage level). In still other embodiments, the phase angle detector 102 may provide phase angle information using both digital and analog formats.

The AC circuitry 12 may receive the phase angle information to control some of its operations. Reference is made to FIGS. 1A and 1B, which are presented merely to illustrate an example.

FIG. 1A shows a functional block diagram of a wireless power transfer system 20, in accordance with another illustrative embodiment. The system 20 may include a transmitter 22 and a receiver 26. The transmitter 22 (also referred to herein as power transfer unit, PTU) may include transmit circuitry 24 that may include an oscillator 32, a driver circuit 34, and a front-end circuit 36. The oscillator 32 may be configured to generate an oscillator signal at a desired frequency that may adjust in response to a frequency control signal 33. The oscillator 32 may provide the oscillator signal to the driver circuit 34. The driver circuit 34 may be configured to drive the power transmitting element 52 at, for example, a resonant frequency of the power transmitting element 52 based on an input voltage signal (V_{D}) 35. The driver circuit 34 may be a switching amplifier configured to receive a square wave from the oscillator 32 and output a sine wave.

The front-end circuit 36 may include a filter circuit configured to filter out harmonics or other unwanted frequencies. The front-end circuit 36 may include a matching circuit configured to match the impedance of the transmitter 22 to the impedance of the power transmitting element 52. The front-end circuit 36 may include a tuning circuit (not shown) to create a resonant circuit with the power transmitting element 52. As a result of driving the power transmitting element 52, the power transmitting element 52 may generate a wireless field 56 to wirelessly output power at a level sufficient for charging a battery 62, or otherwise powering a load.

The transmitter 22 may further include a controller 38 operably coupled to the transmit circuitry 24 and configured to control one or more aspects of the transmit circuitry 24, or accomplish other operations relevant to managing the transfer of power. The controller 38 may be a micro-controller or a processor. The controller 38 may be implemented as an application-specific integrated circuit (ASIC). The controller 38 may be operably connected, directly or indirectly, to each component of the transmit circuitry 24. The controller 38 may be further configured to receive information from each of the components of the transmit circuitry 24 and perform calculations based on the received information. The controller 38 may be configured to generate control signals (e.g., signal 33) for each of the components that may adjust the operation of that component. As such, the controller 38 may be configured to adjust or manage the power transfer based on a result of the operations performed by it. The transmitter 22 may further include a memory (not shown) configured to store data, for example, such as instructions for causing the controller 38 to perform particular functions, such as those related to management of wireless power transfer.

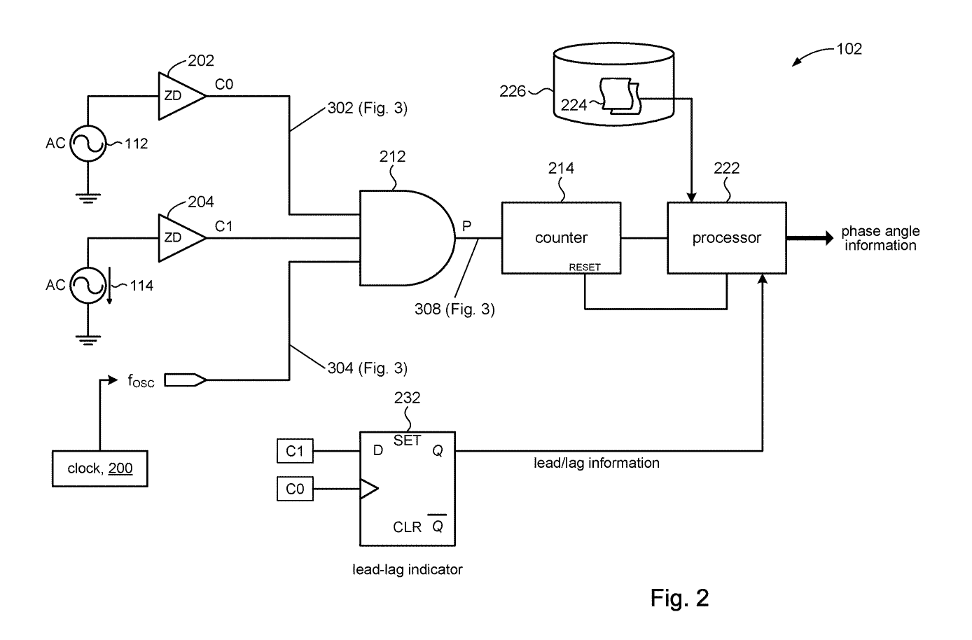

The receiver 26 (also referred to herein as power receiving unit, PRU) may include receive circuitry 28 that may include a front-end circuit 42 and a rectifier circuit 44. The front-end circuit 42 may include matching circuitry configured to match the impedance of the receive circuitry 28 to the impedance of the power receiving element 54. The front-end circuit 42 may further include a tuning circuit (not shown)to create a resonant circuit with the power receiving element 54. The rectifier circuit 44 may generate a DC power output from an AC power input to charge the battery 62, as shown in FIG. 2. The receiver 26 and the transmitter 22 may additionally communicate on a separate communication channel 58 (e.g., Bluetooth, Zigbee, cellular, etc.). The receiver 26 and the transmitter 22 may alternatively communicate via in-band signaling using characteristics of the wireless field 56.

The receiver 26 may be configured to determine whether an amount of power transmitted by the transmitter 22 and received by the receiver 26 is appropriate for charging the battery 62. In certain embodiments, the transmitter 22 may be configured to generate a predominantly non-radiative field with a direct field coupling coefficient (k) for providing energy transfer. Receiver 26 may directly couple to the wireless field 56 and may generate an output power for storing or consumption by a battery (or load) 62 coupled to the output or receive circuitry 28.

The receiver 26 may further include a controller 46 configured similarly to the transmit controller 38 as described above for managing one or more aspects of the wireless power receiver 26. The receiver 26 may further include a memory (not shown) configured to store data, for example, such as instructions for causing the controller 46 to perform particular functions, such as those related to management of wireless power transfer.

Referring to FIG. 1B, transmitter 22 can perform various functions. Some of the functionality may require making measurements of, or otherwise determining, the impedance of the transmitting element 52 and the AC power provided to the transmitting element 52. AC power and/or impedance may be used for many purposes. Illustrative examples include using AC power and/or impedance to control a switching regulator, to avoid cross connection between a PRU and multiple PTU's, to detect the presence of a receiver (e.g., 26), to protect against overloading power amplifier circuitry in the transmitter 22, to detect the presence of foreign or rogue objects (e.g., on a charging surface), to facilitate power sharing, to signal transitions in operating state of the transmitter 22, to enable reverse in-band signaling, and so on. AC power and impedance may be determined from AC voltage, AC current, and the phase angle between the AC voltage and the AC current.

FIG. 1B shows additional details of transmitter 22 for measuring AC power and impedance in accordance with some embodiments of the present disclosure. The transmitter 22 may include a current sensor 72 configured to sense the magnitude of an AC current from the driver 34 to the transmitting element 52. A sensed current signal from the current sensor 72 may be filtered by a low pass filter 74a to produce an AC current signal. A peak detector 76a may provide an analog signal that is proportional to the size of the peak in the AC current signal, which may be converted by an ADC (analog to digital converter, not shown) in the controller 38. Likewise, the transmitter 22 may include a low pass filter 74b to produce an AC voltage signal from the AC voltage across the inputs of the transmitting element 52. A peak detector 76b may provide an analog signal that is proportional to the size of the peak in the AC voltage signal, which may be converted by another ADC (not shown) in the controller 38.

The transmitter 22 may include a phase detector 102 (FIG. 1) in accordance with the present disclosure to provide phase angle information to the controller 38. In some embodiments, for example, the output of low pass filter 74a may serve as the sensed AC current 114 (FIG. 1) that is provided to the phase detector 102. Similarly, the output of low pass filter 74b may serve as the sensed AC voltage 112 (FIG. 1) that is provided to the phase detector 102. The output of phase detector 102 (e.g., phase angle information) may be provided to the controller 38. The controller 38 may compute or otherwise determine the level AC power that is provided to the transmitting element 52 and the impedance of the transmitting element 52 using the AC current, AC voltage, and phase angle information.

In other embodiments, the phase detector 102 may be provided in the receiver 26, for example, to determine AC power or impedance, or for other reasons.

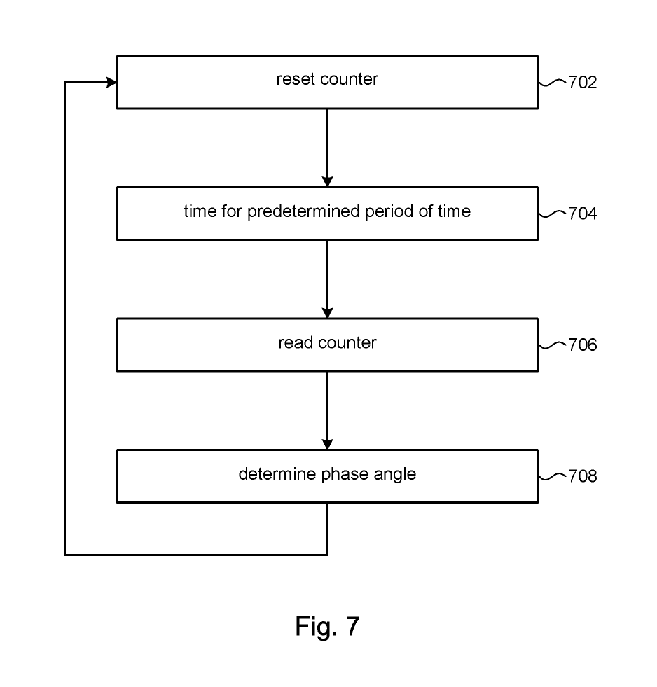

FIG. 2 shows some details of phase angle detector 102 in accordance with some embodiments of the present disclosure. Operation of the circuitry shown in FIG. 2 is described below in connection with FIG. 7. The phase angle detector 102 may include zero crossing detectors 202, 204. The AC voltage signal 112 may be provided to zero crossing detector 202, and likewise, the AC current signal 114 may be provided to zero crossing detector 204. It will be understood that the zero crossing detectors 202, 204 may be implemented using any suitable design. The outputs of the zero crossing detectors 202, 204 may be square wave signals C0, C1 that represent, respectively, the AC voltage signal 112 and the AC current signal 114.

The phase angle detector 102 may include a 3-input AND gate 212. The outputs C0 and C1 of respective zero crossing detectors 202, 204 may be provided to two respective inputs of the AND gate 212. The third input of AND gate 212 may receive a clock signal f_{OSC} from a clock 200.

In some embodiments, the clock 200 may be a component in the phase angle detector 102. In other embodiments, the clock 200 may be a component separate from the phase angle detector 102. In some embodiments, the clock 200 may be a system clock used in the system 10 (FIG. 1), and in other embodiments the clock 200 may be separate from the system clock.

The phase angle detector 102 may include a counter 214. The output P of AND gate 212 may be a square wave, representing the logical AND of the square waves C0, C1, and clock signal f_{OSC}. The output P may be provided to the counter 214. The counter 214 may count the number of pulses in output P. In some embodiments, the counter 214 may count on the rising edges of the pulses in output P. In other embodiments, the counter 214 may count on the falling edges of the pulses in output P. As discussed below, output P may be referred to as an “event signa.”

The phase angle detector 102 may include a processor 222. The processor 222 may be any suitable processing unit, such as but not limited to, a general purpose central processing unit (CPU), a microcontroller, a digital signal processor (DSP), and the like. The output of counter 214 may be provided as a data input to the processor 222. The processor 222 may output a signal to a RESET input on the counter 214 after a predetermined period of time. In accordance with the present disclosure, the processor 222 may use the number of pulses counted by the counter 214 (pulse count) during the predetermined period of time to produce phase angle information indicative of the phase angle between the AC voltage signal 112 and the AC current signal 114. In some embodiments, one or more data tables 224 (e.g., stored in a memory 226) may be used to translate or map the pulse count to another data format in order to represent phase angle in a more suitable format. In other embodiments, the pulse count may be converted to an analog signal (e.g., voltage level or a current level) that represents phase angle.

The phase angle detector 102 may include a lead-lag indicator. In some embodiments, the lead-lag indicator may comprise a D-type flip flop 232. The output C1 of zero crossing detector 204 may be provided to the D input of the D-type flip flop 232. The output C0 of zero crossing detector 202 may be provided to the clock input of the D-type flip flop 232. The SET and CLR (reset) inputs may be held LO so that the D input is copied to the output Q on the rising edges in C0.

The output Q of the D-type flip flop 232 may indicate whether the AC voltage signal 112 leads or lags the AC current signal 114. In the configuration shown in FIG. 2, when the AC voltage signal 112 leads the AC current signal 114 (or stated differently, when AC current lags AC voltage), output Q of the D-type flip flop will be LO. Conversely, when the AC voltage signal 112 lags the AC current signal 114 (or stated differently, when AC current leads AC voltage), output Q of the D-type flip flop will be HI. The lead/lag information at output Q of the D-type flip flop 232 may be provided to the processor 222.

It can be seen from FIG. 2 that phase angle in accordance with the present disclosure is not determined by counting pulses in a clock signal such as f_{OSC}. Instead it was observed that pulses in an event signal such as output P of AND gate 212, other than a clock signal such as f_{OSC}, can provide an indication of the phase angle between AC voltage signal 112 and AC current signal 114. In particular, phase angle can be determined from the number of pulses in the event signal in a given period of time. As described above, an event signal may be produced by combining signals that represent AC voltage signal 112 and AC current signal 114 such as C0, C1 with a clock signal such as f_{OSC}; the event signal is not the same signal as the clock signal.

It was further observed that the accuracy in the phase angle determination was not coupled to the frequency of clock signal f_{OSC}. In other words, accuracy in the determination of phase angle in accordance with the present disclosure may be independent of the clock frequency. Instead, accuracy may be a function of the event signal such as output P of AND gate 212. In particular, it was discovered that counting pulses in the event signal over a longer period of time can increase the accuracy of the phase angle determination. In a particular embodiment, for example, phase angle was determined with an accuracy better than 1% when more than 150 pulses in the event signal were counted. Accordingly, the accuracy of a phase angle can be determined in accordance with the present disclosure without having to increase the clock signal frequency.

Merely to illustrate the point and to provide a sense of the time scales for some embodiments in accordance with the present disclosure, the AC voltage and AC current signals 112, 114 may be 6.78 MHz signals (e.g., for a wireless power transfer system). The clock signal f_{OSC}, however, may be a 32 MHz clock signal. The predetermined period of time for counting pulses by the counter 214, in some embodiments for example, may be in the range 5-10 μS. It will be appreciated, of course, that the AC voltage and AC current signals 112, 114 may be at a frequency other than 6.78 MHz, that a clock frequency other than 32 MHz may be used, and other periods of time may be used to count pulses.

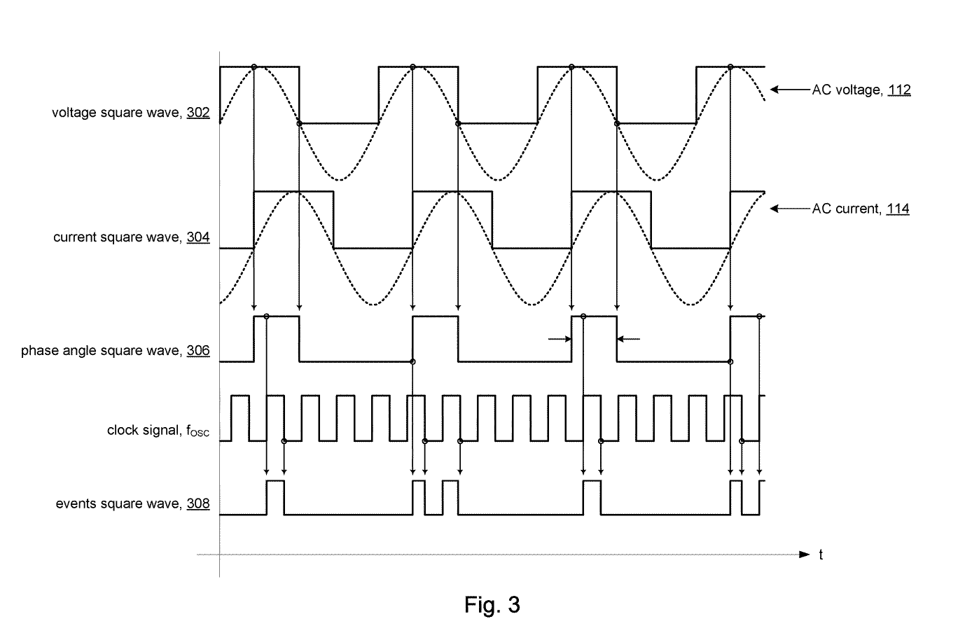

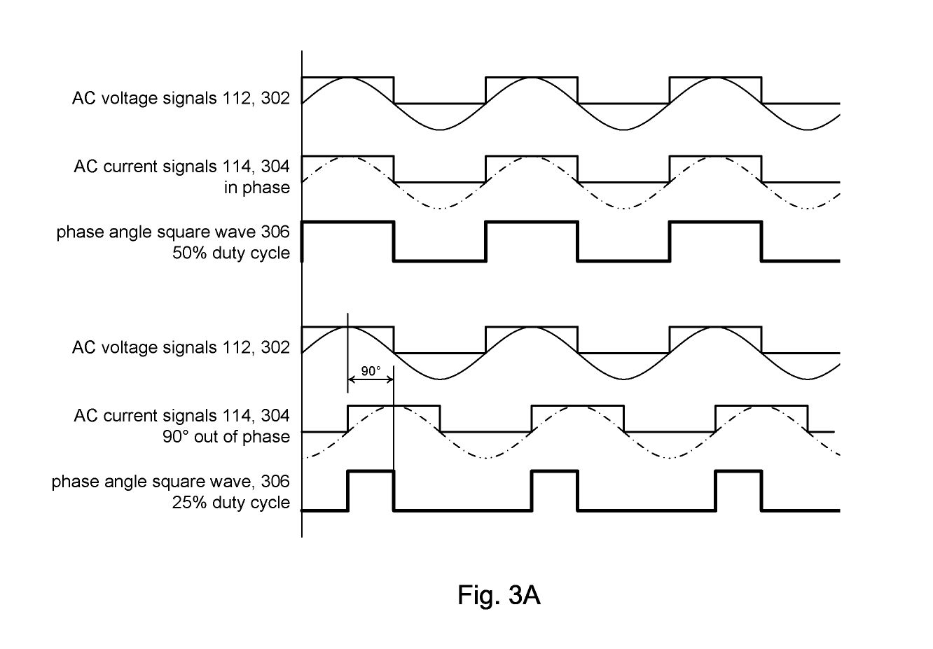

FIGS. 3 and 3A show some waveforms in accordance with some embodiments of the present disclosure. A voltage square wave 302 may be generated from the AC voltage signal 112. For example, the zero crossing detector 202 shown in FIG. 2 may generate the voltage square wave 302. Similarly, a current square wave 304 may be generated from the AC current signal 114; e.g., using the zero crossing detector 204 shown in FIG. 2.

In accordance with the present disclosure, the voltage square wave 302 may be combined with the current square wave 304 to produce a phase angle square wave 306 that represents the phase angle between the AC voltage signal 112 and the AC current signal 114. In some embodiments, for example, the voltage square wave 302 may be AND'd with the current square wave 304 to produce the phase angle square wave 306. As can be seen in FIG. 3A, the duty cycle of the phase angle square wave 306 varies from 50% when the AC voltage and current signals 112, 114 are in phase (0°) to 25% when the AC voltage and current signals 112, 114 are 90° out of phase. In addition, the duty cycle of the phase angle square wave 306 can vary in proportion to the phase angle between the AC voltage and current signals 112, 114.

In accordance with the present disclosure, an events square wave 308 may be generated that represents crossing events between the phase angle square wave 306 and the clock signal f_{OSC}. More particularly, in some embodiments, pulses in the events square wave 308 represent crossing events when both the phase angle square wave 306 and the clock signal f_{OSC} are HI.

In some embodiments, the events square wave 308 may be generated by combining together the AC voltage square wave 302, the AC current square wave 304, and the clock signal f_{OSC}. Referring to FIG. 2, for example, the events square wave 308 may be generated by combining the square wave outputs C0, C1 of respective zero crossing detectors 202, 204 and the clock signal f_{OSC} using the 3-input AND gate 212. The output P of AND gate 212 in FIG. 2 represents an example of events square wave 308 in FIG. 3. The waveforms shown in FIGS. 3 and 3A will be discussed further in connection with FIG. 7.

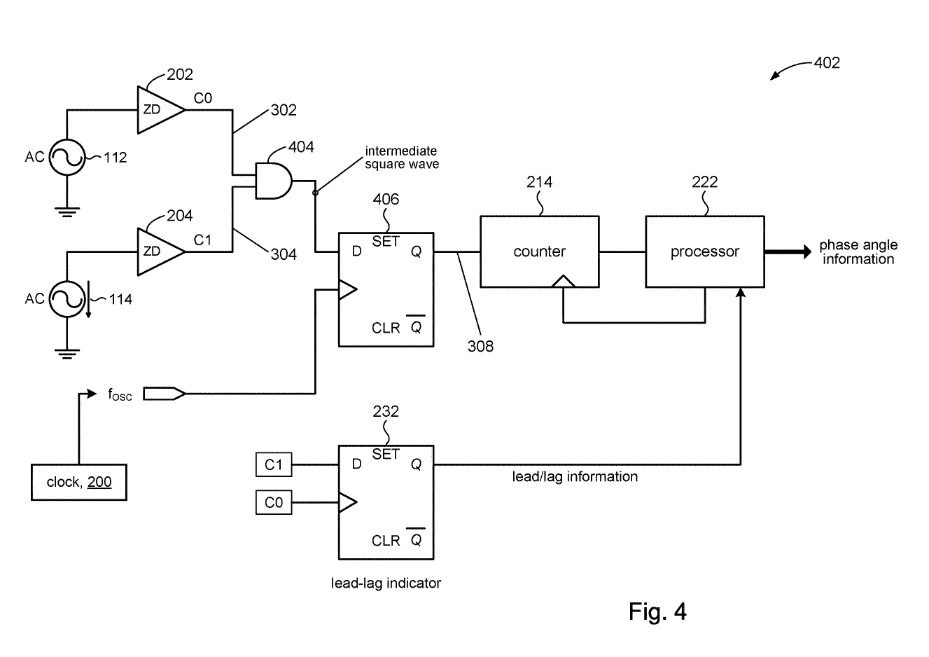

In some embodiments, the phase angle detector 102 (e.g., FIG. 2) may not explicitly generate the phase angle square wave 306 shown in FIG. 3. Referring to FIG. 4, in other embodiments in accordance with the present disclosure, a phase angle detector 402 may generate the phase angle square wave 306 as an explicit signal. Elements in phase angle detector 402 that are common to phase angle detector 102 shown in FIG. 2 may be identified by the same reference numerals. The phase angle detector 402 may include a 2-input AND gate 404. The square wave outputs C0, C1 of respective zero crossing detectors 202, 204 may be provided to respective inputs of the AND gate 404. The output of AND gate 404 may be an intermediate square wave that represents the phase angle between the AC voltage signal 112 and the AC current signal 114, namely phase angle square wave 306, FIG. 3.

The phase angle detector 402 may include a D-type flip flop 406. The output of AND gate 404 may be provided to the D input of the D-type flip flop 406, and the clock signal f_{OSC} may clock the D-type flip flop 406. The output Q of the D-type flip flop 406 may represent an events square wave (e.g., 308, FIG. 3) that represents crossing events between the phase angle square wave output of AND gate 404 (phase angle square wave 306) and the clock signal f_{OSC} in which both square waves are at logic HI. Each crossing event may be represented by a pulse in the output Q of the D-type flip flop 406.

The counter 214 may count the number of pulses in the output Q of the D-type flip flop 406. The output of counter 214 may be provided as an input to processor 222. In accordance with the present disclosure, the processor 222 may use the number of pulses counted by the counter 214 for a predetermined period of time (referred to herein as “pulse count”) to produce phase angle information indicative of the phase angle between AC voltage signal 112 and AC current signal 114. This aspect of the present disclosure will now be discussed.

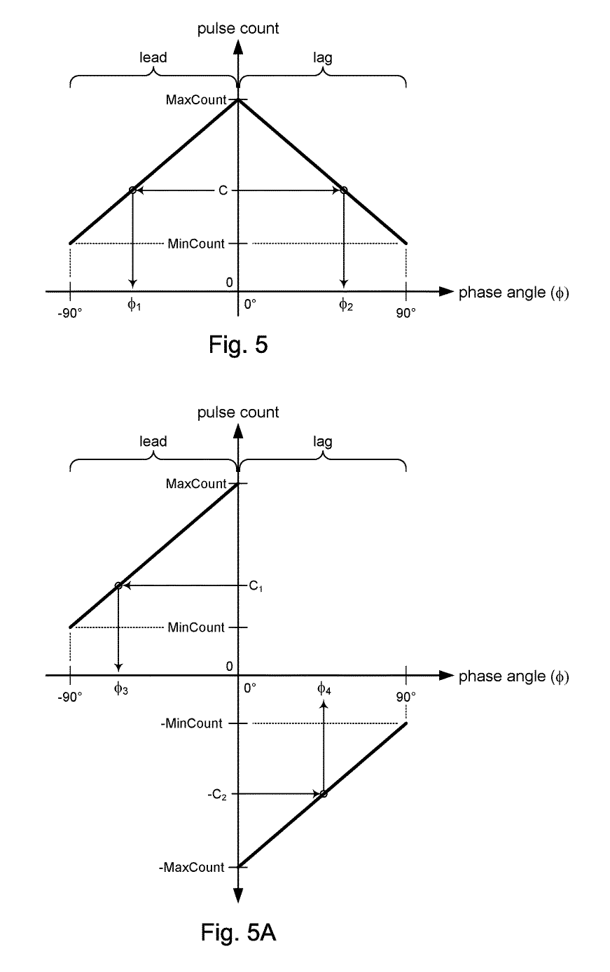

FIG. 5 shows a relationship between pulse count (e.g., of the event square wave 308, FIG. 3) and phase angle expressed as a graph of pulse count (Y-axis) vs. phase angle (X-axis). As mentioned above, pulse count refers to the number of times the phase angle square wave (e.g., 306, FIG. 3) and the clock signal f_{OSC} cross when both square waves are at logic HI, in a given period of time. For example, the number of pulses in the output P of AND gate 212 in FIG. 2 may be counted. Pulse count may be expressed a counts per unit of time; e.g., n/T, where is n is the number of pulses counted over a period of time T.

It was discovered that pulse count can vary linearly with the phase angle between the AC voltage and AC current signals 112, 114. For example, the pulse count may vary from a minimum (MinCount) when the AC voltage and AC current signals 112, 114 are 90° out of phase to a maximum (MaxCount) when the AC voltage and AC current signals 112, 114 are in phase) (0°) in a linear manner. Accordingly, for a given pulse count C, a phase angle φ1 or φ2 may be obtained using the graph shown in FIG. 5. If the AC voltage signal 112 leads the AC current signal 114, then phase angle φ1 may be read from the graph. Conversely, if the AC voltage signal 112 lags the AC current signal 114, then phase angle φ2 may be read from the graph.

The relationship shown in FIG. 5 may be determined empirically. In some embodiments, for example, data may be collected by running circuit simulations. For example, different known settings of phase angles between AC voltage and AC current may be provided. For each phase angle setting, the number of pulses that occur over a given period of time may be recorded to produce a data table of phase angles and corresponding counts. In other embodiments, physical circuits may be built and used to collect the data.

It was noted that the accuracy of the phase angle determination may be improved by counting pulses over a longer period of time. This increased the number of pulses counted; counting more pulses may improve accuracy, without having to increase the clock frequency of the clock signal, e.g., f_{OSC}. Merely to illustrate the point, it was observed that counting at least 150 pulses can provide an accuracy of about 1%. Accordingly, in some embodiments, a time period for counting may be selected so that at least N pulses are counted during that time period. Increasing the time period for counting may increase accuracy.

The graph shown in FIG. 5 may be used when the pulse count is an absolute value. The lead/lag information may come from a separate source. Referring for a moment to FIG. 2, for example, the counter 214 may provide the processor 222 with an absolute value for the pulse count. The lead/lag information may come from the lead-lag indicator (e.g., D-type flip flop 232).

In some embodiments, the pulse count may be a signed value. A positive pulse count may indicate that the AC voltage signal 112 lags the AC current signal 114, while a negative pulse count may indicate that the AC voltage signal 112 leads the AC current signal 114. The graph shown in FIG. 5A may be suitable when the pulse count is a signed value. A leading phase angle can be indicated with a pulse count ranging from MinCount (90° phase angle) to MaxCount (0° phase angle). A lagging phase angle can be indicated with a pulse count ranging from -MinCount to -MaxCount. Since the sign of the pulse count represents the lead/lag information, the leading or lagging phase angle can be determined in a single look up on the graph.

The relationships shown in FIGS. 5 and 5A represent data that may be collected through simulations that assume hypothetical ideal conditions; e.g. the AC voltage signal 112 and the AC current signal 114 are sensed at the same location in the AC circuit 12 (FIG. 1), the interface circuits 14, 16 are identical and do not introduce artifacts into the AC voltage and current signals 112, 114, and so on. In practice, however, the locations A and B (FIG. 1) for sensing voltage and current, respectively, may be different in an actual AC circuit 12. The interface circuits 14, 16 may not be identical and thus may have different frequency response characteristics which may cause additional phase shifts in the AC voltage and/or AC current signals 112, 114. Accordingly, the relationship between pulse count and phase angle may not be symmetrical as shown in FIG. 5.

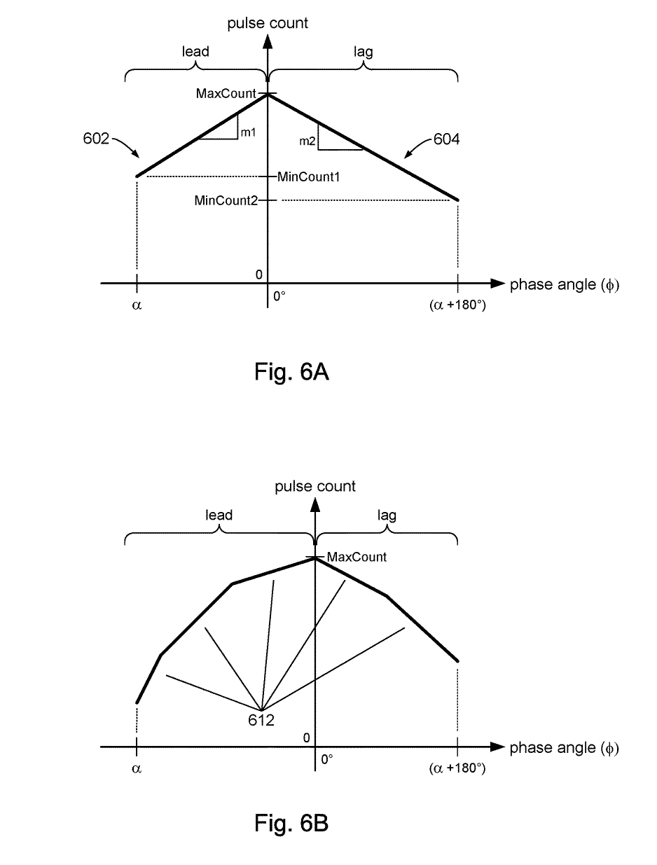

FIG. 6A shows an example of a graph relating pulse count to phase angle associated with a circuit that may account for non-ideal, actual, conditions. The phase angle may not vary from −90° to +90°, but rather may vary between α to (α+180°); ideally, α=−90°, but in practice α≠−90°. A line segment 602 may represent the pulse count vs. phase angle relationship for leading phase angles, while another line segment 604 may represent the pulse count vs. phase angle relationship for lagging phase angles. Pulse counts from MinCount1 to MaxCount may represent leading phase angles from α to 0°, while pulse counts from MaxCount to MinCount2 may represent lagging phase angles from 0° to (α+180°). The graph shown in FIG. 6A is merely illustrative and highlights possible departures from symmetry (e.g., FIG. 5) in a practical circuit. FIG. 6B shows another example of a graph relating pulse count to phase angle that may be associated with a practical circuit. FIG. 6B shows that the pulse count vs. phase angle relationship may be expressed in terms of several line segments 612.

FIG. 7 illustrates an example of processing in the phase detector 102 (FIG. 2) by processor 222 in accordance with some embodiments. At block 702, the processor 222 may reset counter 214 to initiate counting by the counter 214. The counter 214 may begin counting pulses in the signal P (e.g., events square wave 308) from AND gate 212. At block 704, the processor 222 may allow the counter 214 to count for a predetermined period of time, after which time at block 706 the processor 222 may read the output (pulse count) of counter 214; the pulse count represents the number of pulses counted during the predetermined period of time.

At block 708, the pulse count read out of counter 214 at block 706 may be used to determine a phase angle representative of the phase difference between the AC voltage signal 112 and the AC current signal 114. In some embodiments, the relationship (e.g., FIGS. 6A, 6B) between pulse count and phase angle may be stored in one or more data tables (e.g., 224). Phase angles may be stored as entries in the data tables and the pulse count may be used to index into one of the data tables to read out an entry (i.e., a phase angle) corresponding to the pulse count. In some embodiments, separate data tables may be provided for leading phase angles (e.g., line segment 602, FIG. 6A) and for lagging phase angles (e.g., line segment 604, FIG. 6A). The processor 222 may use the lead/lag information (e.g., from D-type flip flop 232) to determine which data table to access.

In some embodiments, the relationship (e.g., FIGS. 6A, 6B) between pulse count and phase angle may be represented using one or more mathematical equations. The relationship shown in FIG. 6A, for example, may be represented by two straight line equations of the form y=mx+b. For example, the line segment 602 may be expressed as:

count=m₆₀₂×φ+MaxCount1, Eqn. 1

where count is the measured number of pulses,
M₆₀₂ is the slope of line segment 602,
MaxCount1 is the y-intercept (b), and
φ is the phase angle, which can be determined from the equation above.
   The line segment 604 may be expressed using a similar equation:

count=m₆₀₄×φ+MaxCount2. Eqn. 2

Accordingly, in some embodiments, block 708 the pulse count read out at block 706 may be used to compute the phase angle using Eqn. 1 or Eqn. 2. A leading phase angle may be computed by the processor 222 using Eqn. 1, while a lagging phase angle may be computed using Eqn. 2. The processor 222 may read in lead/lag information (e.g., from D-type flip flop 232) to determine which equation to use.

In some embodiments, the relationship between pulse count and phase angle may be represented using several line segments, such as shown in FIG. 6B for example. Each line segment may be represented by a suitable straight line equation. More generally, the relationship between pulse count and phase angle may be represented by a function F: φ=F (count).

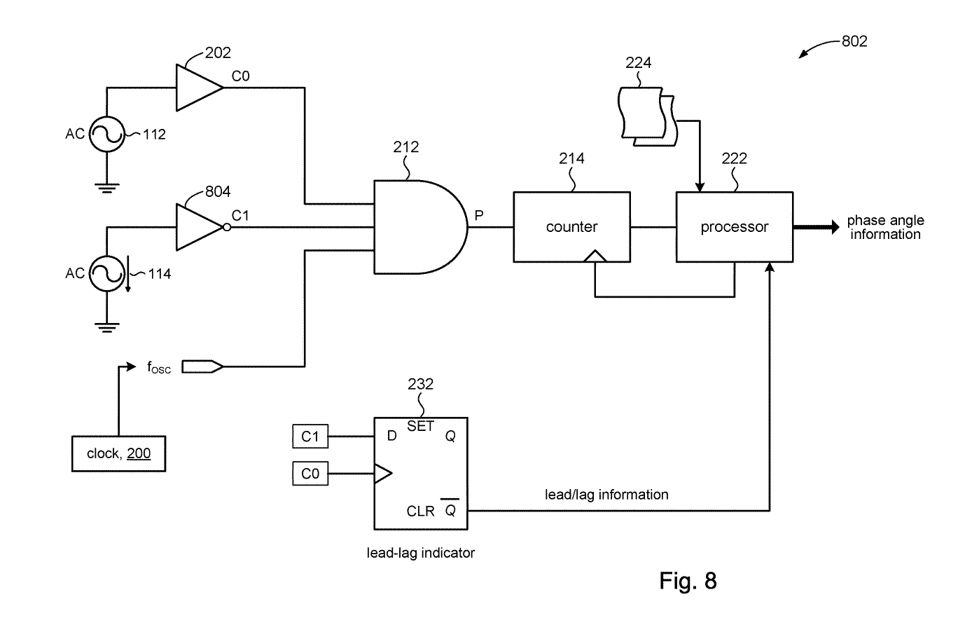

Referring to FIG. 8, in some embodiments, a phase angle detector 802 may comprise a zero crossing detector 804 having an inverted output. Elements in phase angle detector 802 that are common to phase angle detector 102 shown in FIG. 2 may be identified by the same reference numerals. In the particular example shown in FIG. 8, the zero crossing detector 804 is used to generate an inverted square wave output C1 representative of the AC current signal 114. The zero crossing detector 804 is inverted in comparison to the zero crossing detector 204 shown in FIG. 2. In other embodiments (not shown), the zero crossing detector 202 may also be replaced with a inverting zero crossing detector such as zero crossing detector 804 to generate an inverted square wave output C0 representative of the AC voltage signal 112.

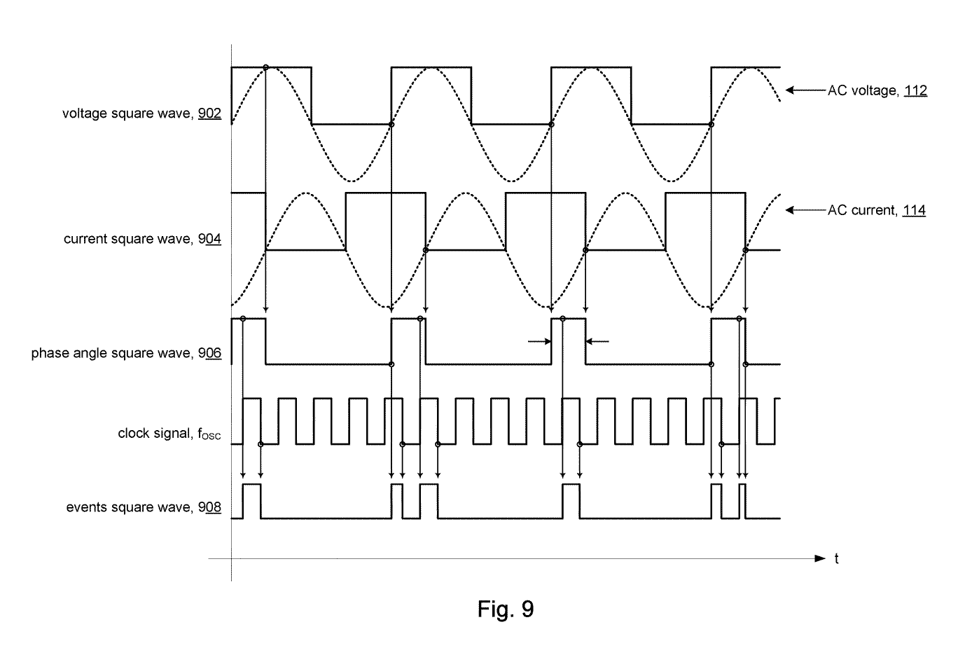

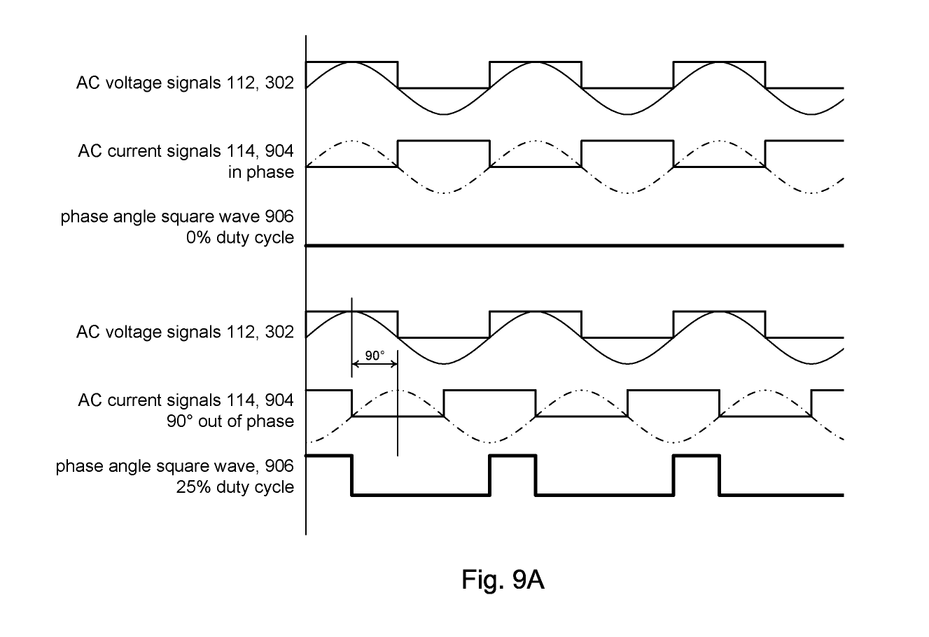

FIGS. 9 and 9A show some waveforms in accordance with some embodiments of the present disclosure that may be generated by the configuration shown in FIG. 8. A voltage square wave 902 may be generated from the AC voltage signal 112. For example, the zero crossing detector 202 shown in FIG. 8 may generate the voltage square wave 902. Similarly, a current square wave 904 may be generated from the AC current signal 114 using the zero crossing detector 804 shown in FIG. 8.

In accordance with the present disclosure, the voltage square wave 902 may be combined with the current square wave 904 to produce a phase angle square wave 906 that represents the phase angle between the AC voltage signal 112 and the AC current signal 114. In some embodiments, for example, the voltage square wave 902 may be AND'd with the current square wave 904 to produce the phase angle square wave 906. As can be seen in FIG. 9A, the duty cycle of the phase angle square wave 906 varies from 0% when the AC voltage and current signals 112, 114 are in phase (0°) to 25% when the AC voltage and current signals 112, 114 are 90° out of phase.

By comparison, using the circuit shown in FIG. 2 (or in FIG. 4), the duty cycle of the phase angle square wave (306, FIG. 3A) can range from 50% (in-phase) to 25% (90° out of phase). The phase angle square wave 306 has more ON time than does the phase angle square wave 906 generated using the embodiment shown in FIG. 8, and thus may increase the number of pulses P provided to the counter 214.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

What is claimed is:

1. A method for determining phase angle in alternating current (AC) signals comprising:
generating a first signal representative of an AC voltage signal;
generating a second signal representative of an AC current signal;
combining the first and second signals with a clock signal to produce a third signal; and
producing phase angle information representative of a phase angle between the AC voltage signal and the AC current signal based on a pulse count indicative of how many pulses occur in the third signal over a predetermined period of time.

2. The method of claim 1, wherein generating the first signal and the second signal include producing respectively a first square wave from the AC voltage signal and a second square wave from the AC current signal.

3. The method of claim 1, wherein combining the first and second signals with a clock signal includes logically AND'ing together the first signal, the second signal, and the clock signal.

4. The method of claim 1, wherein combining the first and second signals with a clock signal includes combining the first and second signals to produce a combined signal and combining the combined signal with the clock signal.

5. The method of claim 4, wherein combining the first and second signals includes logically AND'ing together the first and second signals.

6. The method of claim 1, further comprising providing the phase angle information to a controller in a wireless power transmitting device, wherein the AC voltage signal and the AC current signal are produced in the wireless power transmitting device.

7. The method of claim 1, further comprising determining a sign of the phase angle based only on the first signal and the second signal.

8. The method of claim 1, wherein producing phase angle information includes accessing data in a data table using the pulse count and determining the phase angle using the accessed data.

9. The method of claim 1, wherein producing phase angle information includes evaluating a relationship between phase angle and the number pulses that occur in the third signal over the predetermined period of time.

10. The method of claim 1, wherein an accuracy of the phase angle is independent of a frequency of the clock signal.

11. A method for determining phase angle in alternating current (AC) signals comprising:
generating a first square wave signal representative of an alternating current (AC) voltage signal;
generating a second square wave signal representative of an AC current signal;
generating a third square wave signal by combining at least the first square wave signal and the second square wave signal;
determining a phase angle between the AC voltage signal and the AC current signal based on how many pulses occur in the third square wave in a predetermined period of time.

12. The method of claim 11, further comprising determining a sign of the phase angle based only the first square wave signal and the second square wave signal.

13. The method of claim 11, wherein determining the phase angle is based on data obtained from accessing a data table using the number of pulses that occur in the predetermined period of time.

14. The method of claim 11, wherein determining the phase angle includes evaluating a relationship between phase angle and the number of pulses that occur in the predetermined period of time.

15. The method of claim 11, further comprising logically AND'ing together the first square wave signal, the second square wave signal, and a clock signal to produce a third square wave signal, wherein the phase angle is based on the number of pulses in the third square wave signal during the predetermined period of time.

16. The method of claim 11, further comprising logically AND'ing together the first square wave signal and the second square wave signal to produce an intermediate square wave signal and combining the intermediate square wave signal with a clock signal to produce the third square wave signal.

17. A circuit for determining phase angle in alternating current (AC) signals comprising:
a first circuit configured to generate a first signal representative of an alternating current (AC) voltage signal;
a second circuit configured to generate a second signal representative of an AC current signal;
a third circuit electrically connected to the first and second circuits and configured to combine the first and second signals with a clock signal to produce a third signal;
a counter electrically connected to the third circuit and configured to produce a pulse count representative of a number of pulses occurring in the third signal over a predetermined period of time; and
a computing circuit electrically connected to the counter and configured to produce phase angle data representative of a phase angle between the AC voltage signal and the AC current signal using the pulse count.

18. The circuit of claim 17, wherein the first circuit is a first comparator configured to receive the AC voltage signal and produce a first square wave signal therefrom, wherein the second circuit is a second comparator configured to receive the AC current signal and produce a second square wave signal therefrom.

19. The circuit of claim 18, wherein either the first comparator or the second comparator is further configured to produce an inverted square wave.

20. The circuit of claim 17, wherein the third circuit is an AND gate, the first and second signals are electrically connected to respective first and second inputs of the AND gate, the clock signal is provided to a third input of the AND gate, and the third signal is an output of the AND gate.

21. The circuit of claim 17, wherein the third circuit comprises an AND gate configured to logically AND together the first and second signals to produce an AND'd output and a D-type flip flop electrically connected to the AND gate to receive the AND'd output, the D-type flip flop having a clock input configured to receive the clock signal, the D-type flip flop configured to produce the third signal.

22. The circuit of claim 17, further comprising a fourth circuit electrically connected to the first and second circuits and configured to produce a signal indicative of whether the AC voltage signal leads or lags the AC current signal.

23. The circuit of claim 17, further comprising a memory, wherein the computing circuit comprises a digital processor configured to access data from the memory using the pulse count and to produce the phase angle data using the data accessed from the memory.

24. The circuit of claim 17, wherein the computing circuit comprises a digital processor configured to generate the phase angle data using a relationship between the phase angle and the number of pulses that occur in the third signal over the predetermined period of time.

25. A circuit for determining phase angle in alternating current (AC) signals comprising:
means for generating a first square wave signal representative of an alternating current (AC) voltage signal;
means for generating a second square wave signal representative of an AC current signal;
means for generating a third square wave signal from the first square wave, the second square wave, and a clock signal; and
means for producing phase angle data based on a number of pulses that occur in the third square wave signal in a predetermined period of time.

26. The circuit of claim 25, further comprising means for counting the number of pulses in the third square wave signal that occur during the predetermined period of time, the means for counting configured to provide the number of pulses counted to the means for producing.
